(19) United States
(12) Patent Application Publication
(10) Pub. No.: US 2024/0334755 A1
(43) Pub. Date: Oct. 3, 2024

(54) DISPLAY DEVICE AND MANUFACTURING METHOD THEREOF

(71) Applicant: Samsung Display Co., LTD., Yongin-si (KR)

(72) Inventors: Joon Yong PARK, Yongin-si (KR); Hyun Eok SHIN, Yongin-si (KR); Dong Min LEE, Yongin-si (KR); SAMTAE JEONG, Yongin-si (KR)

(73) Assignee: Samsung Display Co., LTD., Yongin-si (KR)

(21) Appl. No.: 18/398,842

(22) Filed: Dec. 28, 2023

(30) Foreign Application Priority Data
Apr. 3, 2023 (KR) 10-2023-0043672

(51) Int. Cl. H10K 59/123; H10K 59/12; H10K 59/80

(52) U.S. Cl. CPC H10K 59/123; H10K 59/1201; H10K 59/80517

(57) ABSTRACT

According to embodiments, a display device includes a pixel driving circuit including a transistor and disposed on a substrate, an organic layer covering the pixel driving circuit and including a contact hole, a conductive organic layer covering the contact hole and the organic layer around the contact hole and electrically connected to the transistor through the contact hole, a non-conductive organic layer disposed on the organic layer and disposed in a region where the conductive organic layer is not disposed, and an anode electrically connected to the conductive organic layer, and the contact hole overlaps the anode in a plan view.

### CROSS-REFERENCE TO RELATED APPLICATION(S)

This application claims priority to and benefits of Korean Patent Application No. 10-2023-0043672 under 35 U.S.C. § 119 filed in the Korean Intellectual Property Office on Apr. 3, 2023, the entire contents of which are incorporated herein by reference.

### BACKGROUND

### 1. Technical Field

The disclosure relates to a method of manufacturing a display device and a display device, and according to an embodiment, relates to a display device for a head mounted display device and a method for manufacturing thereof.

### 2. Description of the Related Art

The emissive display device is a self-emissive display device that displays an image by emitting light from the light emitting device.

Such an emissive display device is included and used in various electronic devices, and in recent years, head-mounted display devices that are positioned directly in front of the user's eyes and display images in order to provide a three-dimensional or immersive feeling to the user have also become widespread.

The head-mounted display device has a drawback that the light efficiency of the display device is low as a polarizer is used.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The display device may include a pixel driving circuit including a transistor and disposed on a substrate; an organic layer covering the pixel driving circuit and including a contact hole; a conductive organic layer covering the contact hole and the organic layer around the contact hole, and electrically connected to the transistor through the contact hole; a non-conductive organic layer disposed above the organic layer and in a region where the conductive organic layer is not disposed; and an anode electrically connected to the conductive organic layer, wherein the contact hole overlaps the anode on a plan view.

The conductive organic layer may include PEDOT:PSS, and the non-conductive organic layer may have a chemical formula structure in which a thiophene ring is broken in the PEDOT:PSS and separated into two OH groups An anode protective layer positioned at an end of the anode; and an inorganic insulating layer covering the anode protective layer and the non-conductive organic layer. The inorganic insulating layer may have a tip structure protruding from an upper surface of the anode protective layer.

The anode protective layer may include indium-gallium-zinc oxide (IGZO), and the anode is formed as a double layer having a lower layer containing silver and an upper layer including indium tin oxide (ITO), and the ITO of the upper layer of the anode may be polycrystallized.

A separator may be disposed above the organic layer and below the inorganic insulating layer and having a reverse tapered side surface; an intermediate layer disposed above the anode and including an emission layer and a cathode; the intermediate layer being not continuously disposed on the reverse tapered side surface of the separator, a separation intermediate layer separated from the intermediate layer may be further included on an upper surface of the separator.

The intermediate layer may not contact the anode protective layer below the inorganic insulating layer having the tip structure, and an empty space is disposed between the intermediate layer and the anode protective layer.

The intermediate layer may have a tandem structure including a plurality of emission layers.

The separator may be disposed below the non-conductive organic layer, and the non-conductive organic layer and the inorganic insulating layer may be disposed on the reverse tapered side of the separator.

The separator may be disposed on the non-conductive organic layer, and the inorganic insulating layer may be disposed on the reverse tapered side of the separator. A separation cathode may be separated from the cathode on an upper surface of the separator, the cathode being not continuously disposed on the reverse tapered side surface of the separator.

An anode connection line may be covered by the organic layer and electrically connected to the conductive organic layer at a portion thereof through the contact hole, wherein the anode and the transistor are electrically connected to each other by the anode connection line and the conductive organic layer.

The head mounted display device may further include an optical system including a pair of curved lenses.

A method of manufacturing a display device according to an embodiment may include forming a pixel driving circuit including a transistor and disposed on a substrate; forming an organic layer including a contact hole on the substrate; forming and planarizing a conductive organic material on the organic layer; covering a first region of the conductive organic material using a first mask and exposing remaining regions of the conductive organic material; changing the exposed conductive organic material to have non-conductive properties through an oxidation process; and forming an anode corresponding to the first region of the conductive organic material, wherein the conductive organic material in the first region maintains conductivity to complete a conductive organic layer, and the exposed conductive organic material is changed to non-conductive.

The conductive organic material may be PEDOT:PSS, and the conductive organic material loses conductivity by being separated into two OH groups as the thiophene ring is broken by the oxidation process, and may change into a non-conductive organic layer.

The oxidation process may be performed by providing an insulating solution or an etchant capable of breaking the thiophene ring to the conductive organic material.

The forming of the anode may include further heat treatment, and the anode is formed as a double layer including a lower layer containing silver and an upper layer containing indium tin oxide (ITO), and the ITO constituting the upper layer is subjected to the heat treatment can be polycrystallized.

Forming an anode protective layer on the anode corresponding to the first region, forming an inorganic insulating layer exposing a portion of the anode protective layer except for an end thereof by dry etching using a second mask after laminating an inorganic insulating material, and removing the exposed anode protective layer by wet etching.

A portion of the anode protective layer may remain at an end of the anode through the wet etching, and the inorganic insulating layer may have a tip structure protruding from an upper surface of the remaining anode protective layer.

The anode protective layer may include indium-gallium-zinc oxide (IGZO).

According to embodiments, the anode is flattened by filling a conductive organic layer in a contact portion overlapping the anode, thereby reducing light efficiency dispersion that occurs in case that the anode is not flat, and maintaining display quality.

According to embodiments, the anode or the light emitting device may be formed to be relatively large by forming the anode and the emission layer to overlap in the contact portion, and display luminance may be increased through the large light emitting device.

By using the display device according to the embodiment in a head mounted display device, dispersion of light efficiency of the head mounted display device is reduced so that display quality is constant or high luminance can be displayed.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view of a head mounted display device according to an embodiment.

FIG. 2 is a schematic top plan view of a display device according to an embodiment.

FIG. 3 is a schematic cross-sectional view of a display device according to an embodiment.

FIG. 4 to FIG. 11 are drawings for explaining manufacturing procedures of the display device according to the embodiment of FIG. 3.

FIG. 12 and FIG. 13 are schematic cross-sectional views of a display device according to an embodiment.

FIG. 14 is a drawing illustrating a stacked structure of a light emitting device according to an embodiment.

FIG. 15 is a schematic overall cross-sectional view of a display device according to an embodiment.

FIG. 16 is a schematic cross-sectional view of a display device according to a comparative example.

FIG. 17 and FIG. 18 are drawings for explaining the distribution of light efficiency generated in comparative examples.

### DETAILED DESCRIPTION OF THE EMBODIMENTS

Hereinafter, with reference to the accompanying drawings, various embodiments will be described in detail so that a person of an ordinary skill in the art can readily carry out the disclosure.

The disclosure may be embodied in many different forms and is not limited to the embodiments set forth herein.

In order to clearly describe the disclosure, parts irrelevant to the description may be omitted, and the same reference numerals are assigned to the same or similar constituent elements throughout the specification.

Since the size and thickness of each component shown in the drawings are arbitrarily shown for convenience of explanation, the disclosure is not necessarily limited to that which is illustrated.

In the drawings, the thickness of layers, layers, panels, regions, etc., are exaggerated for clarity.

And in the drawings, for convenience of explanation, the thicknesses of some or a number of layers and regions may be exaggerated for convenience.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

Also, when a part such as a layer, film, region, plate, component, etc. is said to be “on” or “on” another part, it includes not only the case “directly above” the other part, but also the case where there is another part in between.

In contrast, when an element is referred to as being “directly on” another element, there are no intervening elements present.

Being “above” or “on” a reference part means being positioned above or below the reference part, and does not necessarily mean being positioned “above” or “on” in the opposite direction of gravity.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Throughout the specification, when it is referred to as “planar image”, it means when the target part is viewed from above, and when it is referred to as “cross-sectional image”, it means when a cross section of the target part cut vertically is viewed from the side.

Throughout the specification, when “connected” is used, this does not mean that two or more constituent elements are directly connected, but when two or more components are indirectly connected through other components, they are physically connected, in addition to being connected or electrically connected, each part that is referred to by different names depending on its location or function but is substantially integral may be connected to each other.

Throughout the specification, when a part such as a wire, layer, film, region, plate, component, etc. “extends in a first direction or a second direction”, it means only a straight line extending in the corresponding direction, instead, it is a structure that generally extends along the first direction or the second direction, and includes a structure that is bent at one part, has a zigzag structure, or extends while including a curved line structure.

Electronic devices (for example, mobile phones, TVs, monitors, notebook computers, etc.) including display devices and display panels described in the specification or display devices and display panels manufactured by the manufacturing method described in the specification the included electronic devices are not excluded from the scope of the specification.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

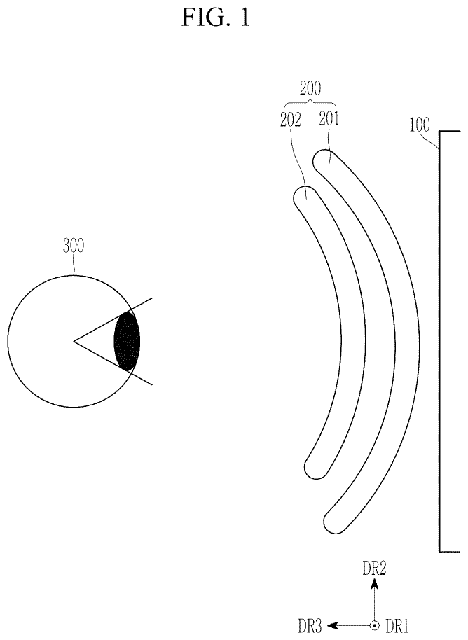

A display device according to the disclosure may be included in various electronic devices, and a schematic structure of a head-mounted display device, which is one embodiment, will be described with reference to FIG. 1.

FIG. 1 is a schematic cross-sectional view of a head mounted display device according to an embodiment.

A head mounted display device according to an embodiment largely may include a display device 100 and an optical system 200 positioned in front of the display device 100.

Here, the head mounted display device may be one of display devices including an optical system.

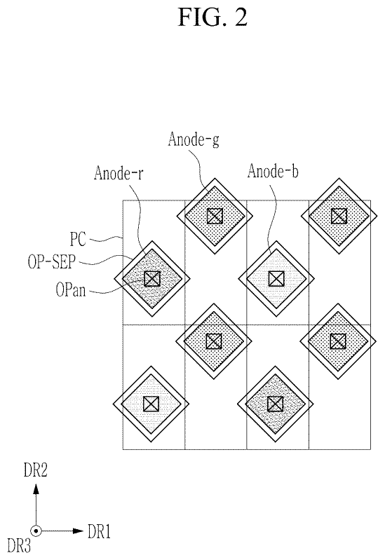

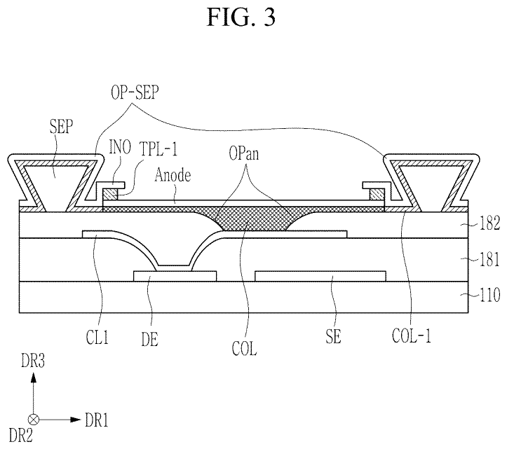

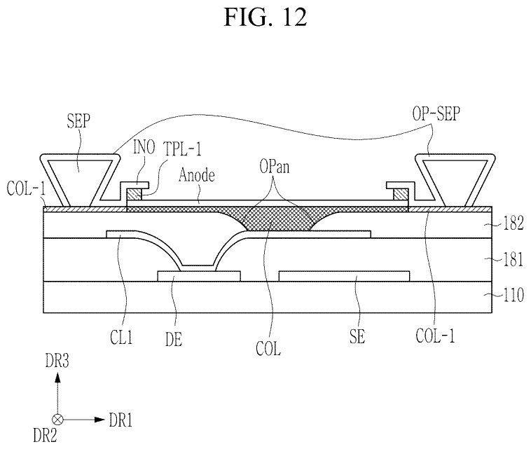

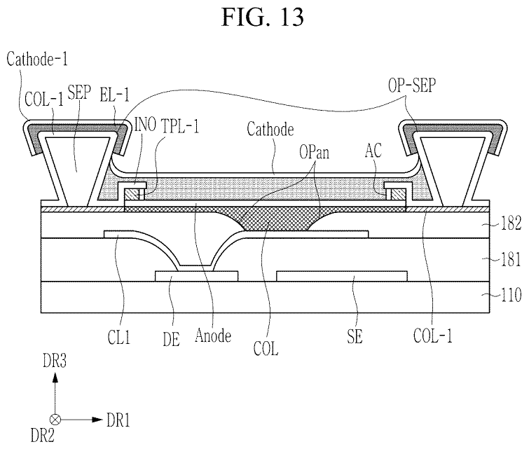

In FIG. 1, the display device 100 may be one of the display devices to be described with reference to FIG. 2, FIG. 3 or FIG. 12, FIG. 13.

The optical system 200 may be positioned between the display device 100 and the user's eye 300 to make the light emitted from the display device 100 appear wider, thereby improving immersion or a three-dimensional effect.

The optical system 200 may include two curved lenses (210, 220; hereinafter also referred to as a pancake lens), and an optical layer may be formed on at least one surface or a surface of each curved lens.

Looking at the optical system 200 according to an embodiment is as follows.

On the side of the display device 100 of the first curved lens (210; hereinafter referred to as a first pancake lens) positioned adjacent to the display device 100 (in the opposite direction to the third direction DR3, also referred to as the inner side) a first retardation plate may be positioned, and a beam splitter is formed on the outer side (side of the third direction DR3).

Here, the first retardation plate is a λ/4 plate, and can change linearly polarized light into circularly polarized light or circularly polarized light into linearly polarized light by providing a phase difference of λ/4 with respect to the delay axis.

The beam splitter transmits half of the incident light and reflects the other half, and may reflect and transmit light regardless of polarization characteristics of the light.

A second retardation plate is formed on the inner side (in the opposite direction to the third direction DR3 of the second curved lens (220; hereinafter referred to as a second pancake lens) positioned adjacent to the user's eye 300, and on the outer side (a reflective polarizing plate may be formed in the third direction DR3 side).

Here, the second retardation plate may also be a λ/4 plate, the reflective polarizing plate has a reflection axis, reflects linearly polarized light of the reflection axis, and transmits linearly polarized light in a direction vertical thereto.

The reflective polarizer may have a wire grid structure in which metal lines having fine widths are arranged or disposed in one direction or in a direction, and may reflect light parallel to the arrangement direction of the metal lines and transmit light vertical thereto.

The interval between the metal lines may be narrower than the wavelength of visible ray.

The first curved lens 200 and the second curved lens 202 included in the optical system 200 may be formed of an optically isotropic material, such as glass or polymethyl methacrylate PMMA can be formed

The curved surfaces of the first curved lens 200 and the second curved lens 202 may be spherical or aspherical.

The display device 100 may be used in a head-mounted display device like the structure of FIG. 1 or used in electronic devices (for example, mobile phone, TV, monitor, laptop computer, etc.).

Hereinafter, the structure of the display device 100 according to various embodiments will be reviewed, and first, the display device 100 according to one embodiment will be reviewed through FIG. 2 and FIG. 3.

Consideration is given to the planar structure.

FIG. 2 is a schematic top plan view of a display device according to an embodiment.

FIG. 2 schematically illustrates pixels included in the display device.

One pixel may include a light emitting device including one pixel driving circuit PC and one anode (Anode-r, Anode-g, Anode-b) electrically connected to the pixel driving circuit PC.

In FIG. 2, the pixel driving circuit part PC is shown in a simplified quadrangular shape, and may include a driving transistor (not shown) generating an output current with anodes (Anode-r, Anode-g, and Anode-b) of the light-emitting device.

The output current of the driving transistor included in the pixel driving circuit PC is transferred to the anodes (Anode-r, Anode-g, and Anode-b) through the contact hole OPan.

The light emitting device further may include an emission layer (not shown) and a cathode (not shown), and the cathode may be formed over the entire display area of the display device.

In the display device according to the embodiment of FIG. 2, a separator (SEP; see FIG. 3) may be positioned above the pixel driving circuit PC and partially overlap the anodes (Anode-r, Anode-g, and Anode-b) there is.

The separator SEP may serve to separate adjacent anodes, and an opening OP-SEP of the separator SEP overlapping the anodes (Anode-r, Anode-g, and Anode-b) is formed.

In FIG. 2, only the opening OP-SEP of the separator SEP is shown, and all parts other than the opening OP-SEP of the separator SEP may be the separator SEP.

Hereinafter, a cross-sectional structure of a display device according to an embodiment will be described with reference to FIG. 3.

FIG. 3 is a schematic cross-sectional view of a display device according to an embodiment.

In FIG. 3, only one anode among the three anodes (Anode-r, Anode-g, Anode-b) is shown as the center, and the structure of the pixel driving circuit PC is also schematically shown.

Referring to FIG. 3, the pixel-driving circuit unit PC is positioned between the first data conductive layer including connecting electrodes (SE, DE) that can be connected to the first and second regions of the transistor positioned on the substrate 110 structure is omitted.

The structure of this part may include at least one transistor (driving transistor), and the stacked structure may vary.

The first substrate 110 may include a rigid material, such as glass, that does not bend, or may include a flexible material that can bend, such as plastic or polyimide.

In the case of a flexible substrate, a double-layered structure of polyimide and a barrier layer formed of an inorganic insulating material thereon may be repeatedly formed.

A transistor including a semiconductor layer and a gate electrode may be formed on the first substrate 110, and a capacitor including two overlapping electrodes may also be formed.

Insulating layers may be included between the semiconductor layer and the electrode for insulation.

A channel is positioned in a portion of the semiconductor layer included in the transistor that overlaps the gate electrode, and a first region and a second region are positioned on both sides of the channel.

A first data conductive layer including connecting electrodes (SE, DE) that may be connected to the first and second regions of the transistor may be positioned on the first substrate 110.

The first data conductive layer may include a metal or metal alloy such as aluminum (Al), copper (Cu), molybdenum (Mo), or titanium (Ti), and may be composed of a single layer or multiple layers.

A first organic layer 181 may be positioned on the first data conductive layer.

The first organic layer 181 may be an organic insulating layer including an organic material, and the organic material may include at least one material selected from the group consisting of polyimide, polyamide, acrylic resin, benzocyclobutene, and phenol resin can do.

A second data conductive layer including an anode connection line CL1 may be positioned on the first organic layer 181.

The second data conductive layer may include a data line or a first voltage line (driving voltage line).

The second data conductive layer may include a metal or metal alloy such as aluminum (Al), copper (Cu), molybdenum (Mo), or titanium (Ti), and may be composed of a single layer or multiple layers.

The anode connection line CL1 is connected to the connecting electrode DE through an opening positioned in the first organic layer 181.

A second organic layer 182 is positioned on the second data conductive layer, the second organic layer 182 may be an organic insulating layer and may include one or more materials selected from the group consisting of polyimide, polyamide, acrylic resin, benzocyclobutene, and phenol resin.

A separator SEP having a lower surface in contact with the second organic layer 182 is formed on the second organic layer 182.

The separator SEP is made of an organic material, and may be made of a transparent organic material or black color to prevent external light from being reflected.

The upper surface of the separator SEP is wider than the bottom surface, and the side surface is formed in a reverse tapered structure.

Due to the reverse tapered side surface, at least one layer or a layer may have a structure in which at least one layer or a layer is separated from each other based on the separator SEP.

Depending on the embodiment, the upper surface of the separator SEP is wide, and a portion of the planar separator SEP may have a structure overlapping a portion of the anode.

A space between adjacent separators SEP constitutes an opening OP-SEP of the separator SEP.

A conductive organic layer COL and a non-conductive organic layer COL-1 are positioned on the second organic layer 182.

The conductive organic layer COL covers the contact hole OPan and the second organic layer 182 around the contact hole OPan, and the transistor (driving transistor) of the pixel driving circuit PC is formed by the contact hole OPan. is electrically connected with.

The non-conductive organic layer COL-1 is on the second organic layer 182 and may be positioned in a region where the conductive organic layer COL is not positioned.

By way of example, the conductive organic layer COL is formed on and around the contact hole OPan formed in the second organic layer 182 and covers the contact hole OPan to make it flat.

Here, the conductive organic layer COL is PEDOT:PSS (Poly(3,4-ethylenedioxythiophene):poly(styrenesulfonate)) may be included.

The conductive organic layer COL has high electrical conductivity and may have flexibility because it is an organic material.

Also, the conductive organic layer COL may have high light transmittance.

The conductive organic layer COL may have a sheet resistance value of less than about 200 Ω/sq, and the sheet resistance value may increase by about 20% in case that heat treated at about 220° C.

The conductive organic layer COL is electrically connected to the anode connection line CL1 through the contact hole OPan, and connects the subsequently formed anode to the transistor through the anode connection line CL1 and the connecting electrode DE allows the output current to be delivered.

The conductive organic layer COL is formed to have a flat structure even in case that the anode positioned thereon is positioned above the contact hole OPan.

In case that the anode has a step, the efficiency of the light emitted from the light emitting device may be dispersed, and the display quality may not be constant, however, this problem does not occur in the embodiment.

A non-conductive organic layer COL-1 is also positioned on the second organic layer 182, and the non-conductive organic layer COL-1 may also be positioned on the separator SEP.

The non-conductive organic layer COL-1 may also be positioned on the sidewall of the separator SEP, and may have a structure that passes over the separator SEP.

The non-conductive organic layer COL-1 may be a portion changed to have non-conductivity through an insulating solution treatment after the conductive organic layer COL is laminated.

According to the insulating solution treatment, S of the thiophene ring of the compound of the conductive organic layer COL is combined with O, and the bond between S and O is changed to an OH group by an additional oxidation process, and the thiophene ring is broken, as it is separated into two OH groups, it loses conductivity and may have non-conductivity.

An anode is positioned on the conductive organic layer COL.

In FIG. 3, the boundary between the anode and the conductive organic layer COL is shown to coincide, however, depending on the embodiment, the boundary between the anode and the conductive organic layer COL may not coincide.

For example, depending on the embodiment, the anode may be in contact with the non-conductive organic layer COL-1.

The anode is electrically connected to the anode connection line CL1 exposed by the contact hole OPan through the conductive organic layer COL, and electrically connected to the transistor positioned at the bottom to transmit the output current of the transistor.

Here, the anode may be formed of a double layer, and may include silver (Ag) as a lower layer and indium-tin oxide ITO as an upper layer.

At this time, the upper layer of the anode formed of ITO (Indium-Tin Oxide) is polycrystallized to prevent the anode from being etched in a subsequent process.

Above the anode, an anode protective layer TPL-1 that is not etched may be positioned at the end of the anode.

The anode protective layer TPL-1 may be positioned along the boundary of the anode.

Depending on the embodiment, only a portion of the anode protective layer TPL-1 may come into contact with the top surface of the anode, and the rest may come into contact with the non-conductive organic layer COL-1.

Here, the anode protective layer TPL-1 may include IGZO (Indium-Gallium-Zinc Oxide), and the layer formed to prevent the lower anode from being etched in a subsequent process is unnecessary in the display device, as a result of wet etching, only a part of the layer remains.

Depending on the embodiment, wet etching may be performed for a long time, so that the anode protective layer TPL-1 may not remain.

An inorganic insulating layer INO is formed on the non-conductive organic layer COL-1 and the anode protective layer TPL-1.

The inorganic insulating layer INO may include an inorganic material such as silicon oxide SiOₓ, silicon nitride SiNₓ, or silicon oxynitride SiONₓ.

In case that an inorganic layer is laminated using chemical vapor deposition CVD, which is capable of stacking the inorganic insulating layer INO even if there is a relatively step difference, the inorganic layer may also be stacked on the reverse tapered side.

The inorganic insulating layer INO positioned on the anode protective layer TPL-1 may further include a tip structure protruding from the top surface of the anode protective layer TPL-1.

The protruding tip structure may occur in case that the anode protective layer TPL-1 is undercut under or below the inorganic insulating layer INO while the anode protective layer TPL-1 is wet-etched.

The inorganic insulating layer INO formed as described above is formed of an inorganic insulating material in order to prevent current from flowing during light emission while the edge portion of the anode and the light emitting device is formed narrowly.

The structure of the inorganic insulating layer INO and the separator SEP combined can play the same role as a pixel defining layer PDL positioned around a general anode.

Although not shown in FIG. 3, referring to FIG. 13, an intermediate layer EL including an emission layer and a cathode may be further included on the anode and the separator SEP.

The light emitting device further may include an intermediate layer EL including an emission layer and a cathode in addition to the anode.

The overall structure of such a light emitting device will be reviewed through FIG. 13.

Referring to FIG. 13, the intermediate layer (see EL in FIG. 13) included in the light emitting device is positioned within the opening OP-SEP of the separator SEP, and is positioned on top of the separator SEP, which is not included in the light emitting device, an isolation intermediate layer (see EL-1 in FIG. 13) may be positioned.

Here, the intermediate layer EL included in the light emitting device may cover the anode and the inorganic insulating layer INO, and does not come into contact with the anode protective layer TPL-1 positioned below the inorganic insulating layer INO, a space (see AC in FIG. 13) may be positioned. Here, the intermediate layer EL included in the light emitting device may cover the anode and the inorganic insulating layer INO, and does not come into contact with the anode protective layer TPL-1 positioned below the inorganic insulating layer INO, a space (see AC in FIG. 13) may be positioned.

A cathode included in the light emitting device (see Cathode in FIG. 13) is formed on the intermediate layer EL, and a separation cathode not included in the light emitting device (see Cathode in FIG. 13) is formed on the separator SEP and the separation intermediate layer EL-1. refer to Cathode-1) may be positioned.

According to the inverted tapered structure of the separator SEP and the inorganic insulating layer INO, as shown in FIG. 13, the cathode may be disconnected without connection.

However, depending on the embodiment, the cathode is formed with damage free sputter equipment having a relatively low incident angle, so that the cathode is also positioned on the side of the separator SEP and the inorganic insulating layer INO and passes over the separator SEP. may have a structure.

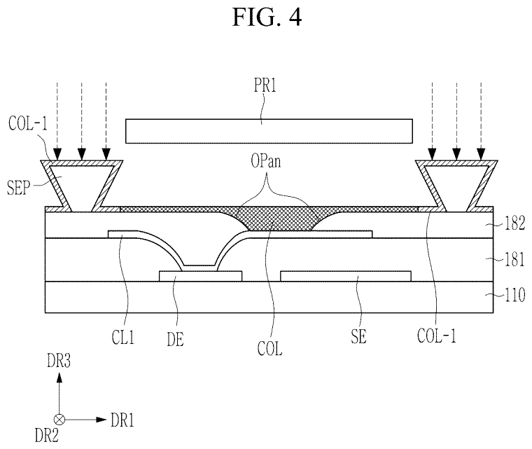

Hereinafter, a detailed manufacturing method of the embodiment of FIG. 3 will be described through FIG. 4 to FIG. 11.

FIG. 4 to FIG. 11 are drawings for explaining manufacturing procedures of the display device according to the embodiment of FIG. 3.

First, a method of forming the conductive organic layer COL and the non-conductive organic layer COL-1 on the second organic layer 182 will be described through FIG. 4 to FIG. 7.

In FIG. 4, processes after the formation of the second organic layer 182 are illustrated, a brief overview of manufacturing processes up to the second organic layer 182 may be as follows.

A first data conductive layer including connecting electrodes SE and DE that can be connected to the first and second regions of the transistor is formed on the substrate 110.

The first data conductive layer may include a metal or metal alloy such as aluminum (Al), copper (Cu), molybdenum (Mo), or titanium (Ti), and may be composed of a single layer or multiple layers.

After that, a first organic layer 181 is deposited on the first data conductive layer.

The first organic layer 181 may include at least one material selected from the group consisting of polyimide, polyamide, acrylic resin, benzocyclobutene, and phenol resin.

At this time, an opening exposing a portion of the connecting electrode DE is formed in the first organic layer 181 so that it can be connected to the anode connection line CL1 in a subsequent process.

After that, a second data conductive layer including an anode connection line CL1 is formed on the first organic layer 181.

The second data conductive layer may include a metal or metal alloy such as aluminum (Al), copper (Cu), molybdenum (Mo), or titanium (Ti), and may be composed of a single layer or multiple layers.

The anode connection line CL1 is connected to the connecting electrode DE through an opening formed in the first organic layer 181.

After that, a second organic layer 182 is deposited on the second data conductive layer.

The second organic layer 182 may include at least one material selected from the group consisting of polyimide, polyamide, acrylic resin, benzocyclobutene, and phenol resin.

At this time, a contact hole OPan exposing a portion of the anode connection line CL1 is formed in the second organic layer 182 so that it can be connected to the conductive organic layer COL and the anode in a subsequent process.

After that, a separator SEP is formed of an organic material on the second organic layer 182.

The upper surface of the separator SEP is wider than the bottom surface, and the side surface is formed in a reverse tapered structure.

Due to the reverse tapered side surface, at least one layer or a layer may have a structure in which at least one layer or a layer is separated from each other based on the separator SEP.

A space between adjacent separators SEP may constitute an opening OP-SEP of the separator SEP.

Referring to FIG. 4, after the conductive organic material is entirely coated on the second organic layer 182 and the separator SEP, a portion not covered by the first mask PR1 is treated with an insulating solution.

As shown in FIG. 4, in case that the entire conductive organic material is coated, the contact hole OPan formed in the second organic layer 182 is covered and flattened.

Thereafter, a portion of the conductive organic material is covered using the first mask PR1 and the remaining portion is exposed.

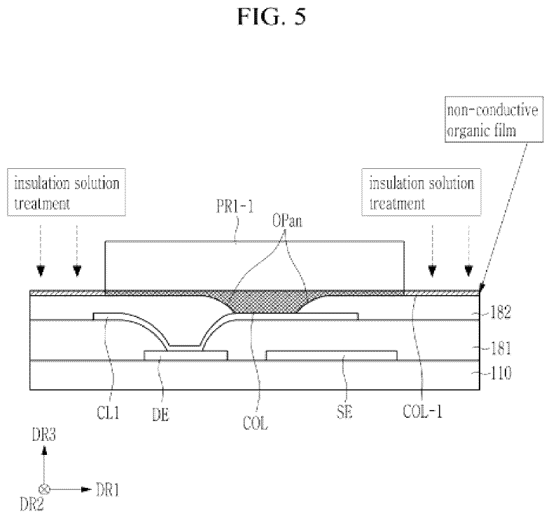

Although FIG. 4 shows that the first mask PR1 covers the conductive organic layer COL, in reality, a photoresist pattern (refer to PR1-1 in FIG. 5) is formed using the first mask PR1, a portion of the conductive organic material may be covered and protected.

Thereafter, by providing an insulating solution, the unprotected portion of the conductive organic material is changed to have non-conductivity by removing conductivity.

As a result, the portion covered by the first mask PR1 maintains conductivity with the conductive organic layer COL, and the portion exposed by the first mask PR1 removes conductivity to form the non-conductive organic layer COL-1 changed.

FIG. 5 to FIG. 7 use PEDOT:PSS, which is a conductive polymer, as a conductive organic material, and examine in detail the removal of conductivity by treatment with an insulating solution.

First, in FIG. 5, a conductive organic material is coated on the second organic layer 182 to planarize it, a photoresist pattern (PR1-1) is formed to protect a portion of the conductive organic material, and an insulating solution treatment is performed, a process of changing the conductive organic material exposed through the non-conductive organic layer COL-1 is shown.

The process of FIG. 5 is divided into forming and planarizing a conductive organic material on the second organic layer 182 covering a first region of the conductive organic material using a first mask PR1, it may be divided into a step of exposing, and a step of changing the exposed conductive organic material to have non-conductivity through an oxidation process.

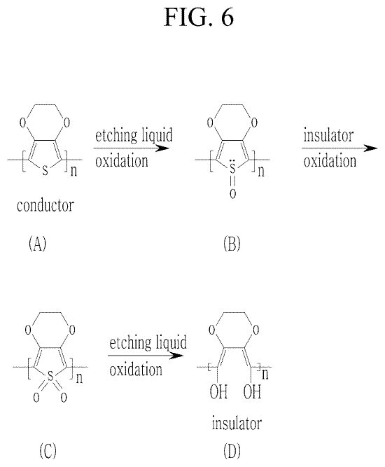

In FIG. 6, the chemical formula shows in what order PEDOT:PSS, which is a conductive organic material, has non-conductive properties by the insulating solution treatment.

The conductive organic material may include a compound as shown in FIG. 6(A).

The compound shown in FIG. 6(A) is a compound having a substituent introduced into a thiophene ring (poly(3,4-ethylenedioxythiophene, PEDOT), and may have conductivity like a conductor.

The conductive organic material having the chemical formula as shown in FIG. 6(A) undergoes an oxidation process in case that an etchant, which is an insulating solution, is provided.

As shown in FIG. 6, the chemical formula of FIG. 6(B) and FIG. 6(C) is changed to the chemical formula of FIG. 6(D) by the oxidation process.

The chemical formula of FIG. 6(D) has non-conductive characteristics like an insulator.

Here, the etchant can break the ring of the compound corresponding to the chemical formula of FIG. 6(A) by a chemical reaction, and as a result, the movement path of electrons is cut off to have non-conductive insulator characteristics.

This etchant may contain water, and any compound capable of breaking the ring of the compound corresponding to the formula of FIG. 6(A) by the oxidation reaction shown in FIG. 6 can be applied as the etchant of the embodiment.

Looking at the oxidation process of FIG. 6 in more detail, in the chemical formula of FIG. 6(A), as shown in FIG. 6(B) and FIG. 6(C), oxygen (O) is bonded to S of the thiophene ring one by one, As shown in FIG. 6(D) by an additional oxidation process, the bond between S and O is changed to an OH group.

For example, as the thiophene ring is broken by the oxidation process, it is separated into two OH groups, and the electron movement path is also broken, and the conductivity is lost, and the organic layer is changed to a non-conductive layer.

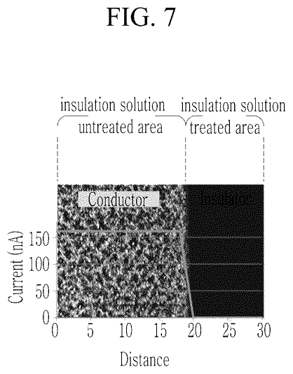

FIG. 7 shows a graph of current values according to positions on a photograph of a conductive organic material PEDOT:PSS treated with an insulating solution and a non-treated portion.

As can be seen from the graph of FIG. 7, it can be seen that the region where the insulating solution is not treated has the characteristics of a conductor and the current can flow by about 150 nA, and the region where the insulating solution is treated is an insulator, it can be confirmed that current does not flow.

As described above, it can be confirmed that the conductivity of the corresponding portion can be removed by treating a portion of the conductive organic material with the insulating solution.

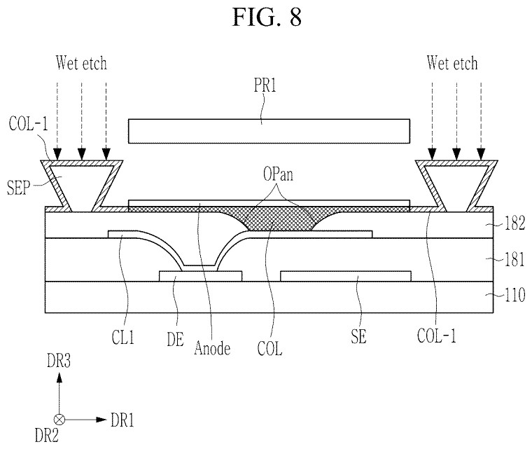

After the process of FIG. 4 is completed, a process of forming an anode is performed as shown in FIG. 8.

Referring to FIG. 8, the conductive material for the anode is stacked entirely on the conductive organic layer COL and the non-conductive organic layer COL-1, and wet etch by the first mask PR1 to complete the anode.

Although FIG. 8 shows that the first mask PR1 covers the anode, in reality, a photoresist pattern is formed using the first mask PR1 to cover and protect a portion of the conductive material for the anode, it can be wet etched.

Here, the first mask PR1 of FIG. 8 may be the same as the first mask PR1 of FIG. 4, and different masks may be used depending on embodiments.

If the mask is not changed, the manufacturing cost may be reduced merit because the mask is not separately manufactured.

In FIG. 8, since the same first mask PR1 as in FIG. 4 is used, an anode is formed in the same pattern as that of the conductive organic layer COL, and the boundary of the anode is the boundary of the conductive organic layer COL can match.

However, misalignment may occur, so that the borders may be formed offset from each other.

As shown in FIG. 8, after the anode is formed through wet etching, the anode may be polycrystallized through heat treatment.

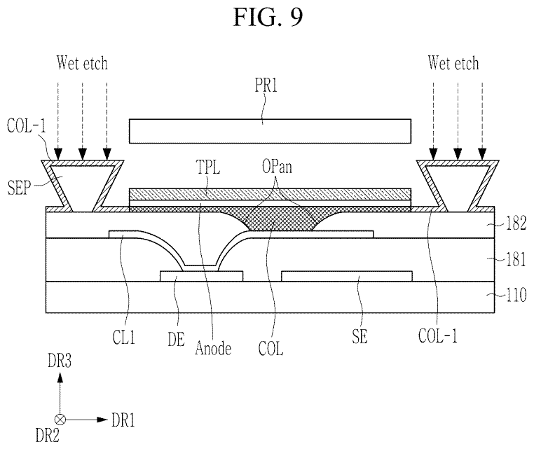

In case that the anode is polycrystallized, in case that wet etching is performed in FIG. 9, this is to prevent the exposed portion of the anode positioned at the bottom from being etched.

According to an embodiment, the anode may be formed of a double layer, and may include silver (Ag) as a lower layer and indium-tin oxide ITO as an upper layer.

At this time, the heat treatment can be carried out at 220° C. for 1 hour, and as a result, the ITO of the upper layer of the anode may be polycrystallized, and in case that wet etching is performed in FIG. 9, the exposed anode may not be etched.

Thereafter, referring to FIG. 9, the anode protection material is laminated on top of the non-conductive organic layer COL-1 and the anode, and wet etched by the first mask PR1 to complete the anode protection layer TPL.

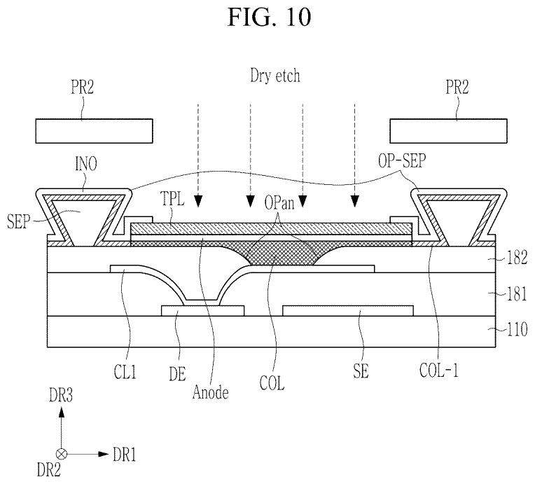

Here, the anode protection material may comprise Indium-Gallium-Zinc Oxide IGZO, and is a layer for preventing the lower anode from being etched during dry etching in the subsequent process of FIG. 10.

Although FIG. 9 shows that the first mask PR1 covers the anode protection layer TPL, in reality, the first mask PR1 is used to form a photoresist pattern to cover a part of the anode protection material to protect and wet etch.

Here, the first mask PR1 of FIG. 9 may be the same as the first mask PR1 of FIG. 4 and FIG. 8, and different masks may be used according to an embodiment.

If the mask is not changed, the mask is not manufactured separately, which can have the merit of reducing the manufacturing cost.

Since the same first mask PR1 as in FIG. 4 and FIG. 8 is used in FIG. 9, an anode protection layer TPL is formed in the same pattern as the conductive organic layer COL and the anode, and the boundary of the anode protection layer TPL may coincide with the boundary of the conductive organic layer COL and the anode.

However, misalignment may occur, causing boundaries to be formed by offsetting each other.

Thereafter, referring to FIG. 10, the inorganic insulating material is laminated on top of the non-conductive organic layer COL-1 and the anode protective layer TPL, and dry etched by the second mask PR2 to complete the inorganic insulating layer INO.

Here, the inorganic insulating material may comprise one of silicon oxide SiOₓ, silicon nitride SiNₓ, and silicon oxynitride SiONₓ, and in an embodiment, silicon nitride SiNₓ can be used to form an inorganic insulating layer INO.

Although FIG. 10 shows that the second mask PR2 covers the inorganic insulating layer INO, in reality, the second mask PR2 is used to form a photoresist pattern to cover and protect a portion of the inorganic insulating material.

During dry etching to form an inorganic insulating layer INO, the anode protective layer TPL may be exposed.

IGZOs that make up the anode protective layer TPL are low in volatility that react with gases, so they serve as an etch stop layer during dry etching used to form inorganic insulating layers INO.

Therefore, the anode positioned at the bottom of the anode protection layer TPL can be protected from dry etching.

Referring to FIG. 10, the inorganic insulating layer INO has a structure covering the end of the anode protective layer TPL.

By way of further example, the inorganic insulating layer INO covers all the ends of the anode protection layer TPL and the portion where the anode protection layer TPL is not positioned, and only the rest of the anode protection layer TPL except the end of the anode protection layer TPL can be exposed.

This structure is disposed so that the second mask PR2 also protects a portion of the anode protective layer TPL.

As a result, the anode protection layer TPL and the end of the anode positioned below it may have a structure covered with an inorganic insulating layer INO.

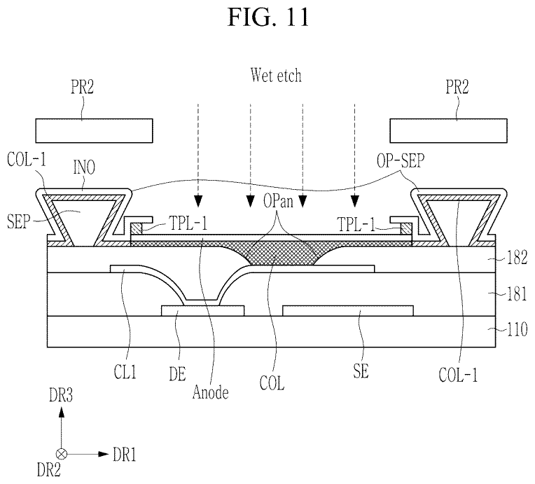

Thereafter, as shown in FIG. 11, the anode protection layer TPL exposed through wet etching is etched while the inorganic insulating layer INO is protected using a second mask PR2.

According to an embodiment, the second mask PR2 of FIG. 10 and FIG. 11 may be the same, and the anode protection layer TPL exposed may be etched by providing an etch solution without removing the photoresist pattern formed to form FIG. 10.

Referring to FIG. 11, in case that the exposed anode protection layer TPL is wet-etched, the anode protection layer TPL positioned below the end of the inorganic insulating layer INO is undercut, and the anode protection layer TPL is not entirely etched and partially remains to form the anode protection layer TPL-1.

As a result, the edge portion of the inorganic insulating layer INO may have a protruding tip structure.

According to an embodiment, the anode protection layer TPL-1 may be etched and removed entirely.

Through the above manufacturing method, the cross-sectional structure of FIG. 3 can be manufactured.

As shown above, as shown in FIG. 3, a non-conductive organic layer COL-1 is also formed on the separator SEP in addition to the inorganic insulating layer INO, and according to an embodiment, a non-conductive organic layer COL-1 may be positioned at the bottom of the separator SEP.

Hereinafter, through FIG. 12 and FIG. 13, a non-conductive organic layer COL-1 is positioned at the bottom of the separator SEP, and only the inorganic insulating layer INO is positioned on the separator SEP.

FIG. 12 and FIG. 13 are schematic cross-sectional views of a display device according to an embodiment.

In FIG. 12, only the structure up to the inorganic insulating layer INO and the anode is shown in a cross-sectional view corresponding to FIG. 3, and in FIG. 13, a structure up to the interlayer EL and the cathode is shown in addition to FIG. 12.

FIG. 12 differs from the structure of FIG. 3 at least in that the non-conductive organic layer COL-1 is above the second organic layer 182 and is positioned below the separator SEP.

As a result, the non-conductive organic layer COL-1 is not positioned on the upper surface and side wall of the separator SEP, and only the inorganic insulating layer INO can be positioned on the upper surface and side wall of the separator SEP.

In FIG. 12, the structure excluding the non-conductive organic layer COL-1 is as shown in FIG. 3, so the description is omitted.

FIG. 13 shows a structure in which an intermediate layer EL including a light-emitting layer and a cathode are further formed on top of FIG. 12 according to an embodiment.

Referring to FIG. 13, the intermediate layer EL and the cathode may be divided into separate intermediate layers (EL, EL-1) and cathodes (Cathode, Cathode-1).

Specifically, the intermediate layer may be divided into an intermediate layer EL included in the light emitting device and a separation intermediate layer EL-1 not included in the light emitting device, and the cathode may be a cathode included in the light emitting device and not included in the light-emitting device, it can be divided into a separate cathode Cathode-1 that does not.

The intermediate layer EL included in the light emitting device is positioned within the opening OP-SEP of the separator SEP, and the separation intermediate layer EL-1 not included in the light emitting device is placed on the separator SEP and the inorganic insulating layer INO can be positioned.

Here, the intermediate layer EL included in the light emitting device may cover the anode at most positions and may cover the inorganic insulating layer INO at a portion adjacent to the separator SEP.

Under or below the protruding tip structure of the edge portion of the inorganic insulating layer INO, the intermediate layer EL may not contact the anode protective layer TPL-1, and the anode protective layer TPL-1 and the intermediate layer an empty space (AC) may be formed between EL.

A cathode included in the light emitting device is formed on the intermediate layer EL, and a separator SEP, an inorganic insulating layer INO, and an isolation intermediate layer EL-1 are separated from the light emitting element, a cathode Cathode-1 may be positioned.

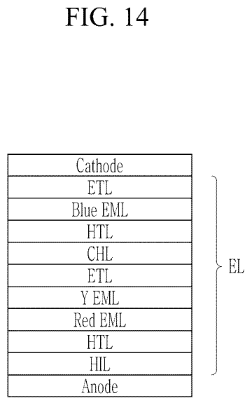

Here, the anode (Anode), the intermediate layer EL, and the cathode (Cathode) constitute a light emitting device, and the laminated structure of the light emitting device may include emission layers as shown in FIG. 14.

Due to the reverse tapered structure of the separator SEP and the inorganic insulating layer INO, a separation intermediate layer EL-1 and a separation cathode Cathode-1 separated from the intermediate layer EL and the cathode may be formed.

However, depending on the embodiment, the cathode is formed with damage free sputter equipment having a relatively low incident angle, so that the cathode is also positioned on the side of the separator SEP and the inorganic insulating layer INO, and rides on the separator SEP. A skipping structure may also be included.

Depending on embodiments, the separator SEP may be omitted.

Hereinafter, a stacked structure of a light emitting device according to an embodiment will be described with reference to FIG. 14.

FIG. 14 is a drawing illustrating a stacked structure of a light emitting device according to an embodiment.

In FIG. 14, a laminated structure of an intermediate layer EL positioned between an anode and a cathode is shown in detail.

In FIG. 14, emission layers (Blue EML, Y EML, and Red EML) are formed, and hereinafter, this is also referred to as a tandem structure.

In the embodiment of FIG. 14, a total of three emission layers (Blue EML, Y EML, Red EML) are included between the anode and the cathode.

A hole injection layer HIL, a hole transport layer HTL, an electron transport layer ETL, and a connection layer CHL are included above and below each emission layer (Blue EML, Y EML, and Red EML).

Depending on the embodiment, an electron injection layer may also be included.

Specifically, in the embodiment of FIG. 14, a hole injection layer HIL and a hole transport layer HTL are sequentially positioned on an anode, and a first color emission layer (Red EML) and a second color emission layer are thereon, (Y EML) is positioned.

Specifically, in the embodiment of FIG. 14, a hole injection layer HIL and a hole transport layer HTL are sequentially positioned on an anode, and a first color emission layer (Red EML) and a second color emission layer are thereon, (Y EML) is positioned.

An electron transport layer ETL is positioned on the third color emission layer (Blue EML), and a cathode is positioned thereon.

Here, the connection layer CHL is positioned between the electron transport layer ETL and the hole transport layer HTL, and serves to lower the fermi barrier between the two layers.

The connection layer CHL may also be referred to as a Charge Generation Layer.

The first color may be red, the second color may be yellow, and the third color may be blue.

Depending on embodiments, green may be used instead of yellow as the second color.

Since wavelengths of different colors are emitted from the three emission layers (Blue EML, Y EML, and Red EML) in the intermediate layer as described above, white light may be emitted as a whole.

Depending on the embodiment, at least one layer or a layer of a hole injection layer, a hole transport layer, an electron transport layer, and an electron injection layer may be further included between the emission layers (Blue EML, Y EML, Red EML).

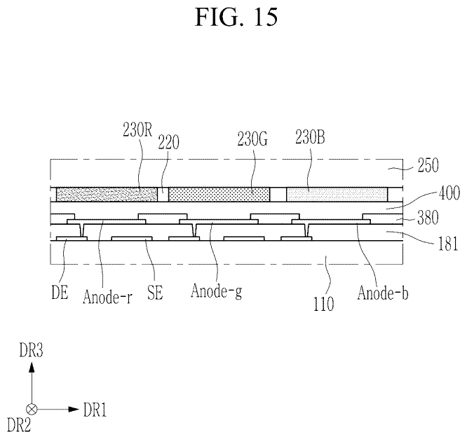

Since each light emitting device emits white light, the display device may additionally include a color filter or a color conversion layer to display color, and this structure will be reviewed with reference to FIG. 15.

Hereinafter, a cross-sectional structure of the entire display device, which describes the upper structure of the display device in more detail, will be reviewed through FIG. 15.

FIG. 15 is a schematic entire cross-sectional view of a display device according to an embodiment.

In FIG. 15, similar to the other schematic cross-sectional views, the area between the substrate 110 and the first data conductive layer including the connecting electrodes (SE, DE) is not shown.

A structure between the substrate 110 and the first data conductive layer including the connecting electrodes (SE, DE) according to an embodiment may be described as follows.

The first substrate 110 may include a rigid characteristic, such as glass, that does not bend, or may include a flexible material that can bend, such as plastic or polyimide.

In the case of a flexible substrate, a double-layered structure of polyimide and a barrier layer formed of an inorganic insulating material thereon may be repeatedly formed.

A buffer layer covering the first substrate 110 is positioned.

The buffer layer serves to block penetration of impurity elements into the first semiconductor layer, and may be an inorganic insulating layer including silicon oxide SiOₓ, silicon nitride SiNₓ, or silicon oxynitride SiONₓ.

Depending on the embodiment, a lower shielding layer overlapping the channel of the transistor and including a metal may be further included between the first substrate 110 and the buffer layer.

A first semiconductor layer formed of a silicon semiconductor (for example, polycrystalline semiconductor (P—Si)) is positioned on the buffer layer.

The first semiconductor layer may include a channel of a polycrystalline transistor including a driving transistor and first region and second region positioned on both sides of the channel.

Here, the polycrystalline transistor may be other switching transistors as well as a driving transistor.

Both sides of the channel of the first semiconductor layer may have a region having conductive layer characteristics by plasma treatment or doping, thereby serving as the first and second electrodes of the transistor.

A first gate insulating layer may be positioned on the first semiconductor layer.

The first gate insulating layer may be an inorganic insulating layer including silicon oxide SiOₓ, silicon nitride SiNₓ, or silicon oxynitride SiONₓ.

A first gate conductive layer including a gate electrode of a polycrystalline transistor may be positioned on the first gate insulating layer.

A scan line or an emission control line may be formed in the first gate conductive layer in addition to the gate electrode of the polycrystalline transistor.

After forming the first gate conductive layer, an exposed region of the first semiconductor layer may be made conductive by performing a plasma treatment or a doping process.

For example, the first semiconductor layer covered by the gate electrode is not conductive, and a portion of the first semiconductor layer not covered by the gate electrode may have the same characteristics as the conductive layer.

A second gate insulating layer may be positioned on the first gate conductive layer and the first gate insulating layer.

The second gate insulating layer may be an inorganic insulating layer including silicon oxide SiOₓ, silicon nitride SiNₓ, or silicon oxynitride SiONₓ.

A second gate conductive layer including one electrode of the first capacitor may be positioned on the second gate insulating layer.

One electrode of the first capacitor may overlap the gate electrode of the driving transistor to form the first capacitor.

A first interlayer insulating layer may be positioned on the second gate conductive layer.

The first interlayer insulating layer may include an inorganic insulating layer including silicon oxide SiOₓ, silicon nitride SiNₓ, silicon oxynitride SiONₓ, or the like, and depending on embodiments, an inorganic insulating material may be formed thickly.

A first data conductive layer including connecting electrodes SE and DE capable of being connected to the first and second regions of the polycrystalline transistor may be positioned on the first interlayer insulating layer.

The first data conductive layer may include a metal or metal alloy such as aluminum (Al), copper (Cu), molybdenum (Mo), or titanium (Ti), and may be composed of a single layer or multiple layers.

Depending on embodiments, an oxide transistor may be included between the first interlayer insulating layer and the first data conductive layer, and the oxide transistor may be formed in a layered structure as described below.

A second semiconductor layer (oxide semiconductor layer) including a second semiconductor including a channel of an oxide transistor, a first region, and a second region may be positioned on the first interlayer insulating layer.

A third gate insulating layer may be positioned on the second semiconductor layer.

The third gate insulating layer may be positioned on the entire surface of the second semiconductor layer and the first interlayer insulating layer.

A third gate conductive layer including a gate electrode of an oxide transistor may be positioned on the third gate insulating layer.

A gate electrode of the oxide transistor may overlap the channel, and the third gate conductive layer may further include a scan line or a control line.

A second interlayer insulating layer may be positioned on the third gate conductive layer.

As shown in FIG. 15, a first organic layer 181 may be positioned on the first data conductive layer including the connecting electrodes (SE, DE).

The first organic layer 181 may be an organic insulating layer including an organic material, and the organic material may include at least one material selected from the group consisting of polyimide, polyamide, acrylic resin, benzocyclobutene, and phenol resin can do.

Anodes (Anode-r, Anode-g, Anode-b) are formed on the first organic layer 181.

An additional data conductive layer or an organic layer may be further positioned between the first organic layer 181 and the anodes (Anode-r, Anode-g, Anode-b) depending on embodiments.

The structure on the first organic layer 181 and the anode (Anode-r, Anode-g, Anode-b) may vary for each embodiment, and in FIG. 15, one of them, the pixel defining layer 380 is shown.

The pixel defining layer 380 may be a black pixel defining layer formed of a black organic material to prevent externally applied light from being reflected back to the outside, or may be formed of a transparent organic material according to embodiments.

Spacers may be further formed on the pixel defining layer 380 according to embodiments.

Depending on embodiments, a separator may be positioned instead of the pixel defining layer 380, and a separator may be positioned on the pixel defining layer 380.

An intermediate layer including an emission layer and a cathode are positioned above the anodes (Anode-r, Anode-g, Anode-b), but are omitted in FIG. 15.

A light emitting device including anodes (Anode-r, Anode-g, Anode-b), an intermediate layer, and a cathode may be a white light emitting device emitting white color, and an encapsulation layer 400 is positioned on the light-emitting device.

The encapsulation layer 400 may include at least one inorganic layer and at least one organic layer, and may have a triple layer structure including a first inorganic encapsulation layer, an organic encapsulation layer, and a second inorganic encapsulation layer.

The encapsulation layer 400 may be for protecting the emission layer from moisture or oxygen that may be inflowed from the outside.

Depending on the embodiment, the encapsulation layer 400 may include a structure in which an inorganic layer and an organic layer may be sequentially stacked each other.

A light blocking layer 220 and color filters (230R, 230G, 230B) are positioned on the encapsulation layer 400.

The color filters (230R, 230G, 230B) allow each light emitting device to display a color in case that the light-emitting device emits white color, thereby enabling color display.

Depending on embodiments, each light emitting device may display one of three primary colors, and a color filter may be omitted.

Depending on the embodiment, in case that the light emitting device emits blue light, a color conversion layer may be further included to convert the blue light into red or green to display color.

The light blocking layer 220 may block light so that light passing through the color filters (230R, 230G, 230B) is not mixed with each other.

Depending on embodiments, a sensing insulating layer and sensing electrodes may be included above or below the light blocking layer 220 and the color filters (230R, 230G, 230B) to sense a touch.

Depending on the embodiment, a layer including a polarizing plate is attached to the light blocking layer 220 and the color filters (230R, 230G, 230B) to reduce reflection of external light, or a material capable of absorbing some wavelengths of external light (a layer in which a reflection adjusting material) is formed may be further included.

In the above, the structures of various embodiments have been examined.

Hereinafter, in relation to the feature of the disclosure that the dispersion of light efficiency is reduced according to the planarization of the anode, the occurrence of dispersion of light efficiency in the comparative example will be examined.

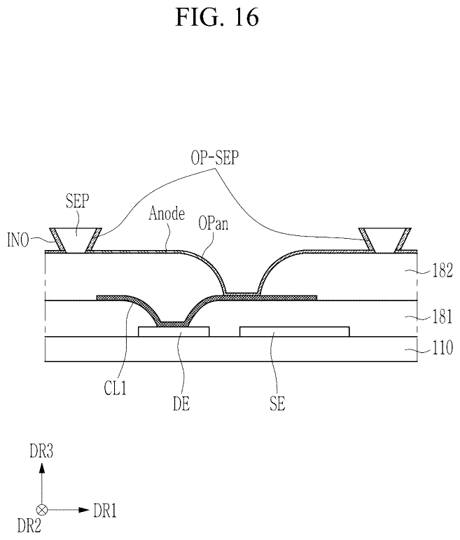

First, in FIG. 16, a schematic cross-sectional structure of a comparative example is shown.

FIG. 16 is a schematic cross-sectional view of a display device according to a comparative example.

Referring to FIG. 16, an anode is positioned on top of the second organic layer 182 and is electrically connected to the lower anode connection line CL1 through a contact hole OPan formed in the second organic layer 182.

At this time, the anode has a non-flat structure around the contact hole OPan due to the step of the contact hole OPan.

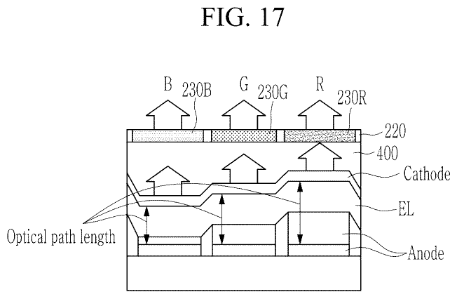

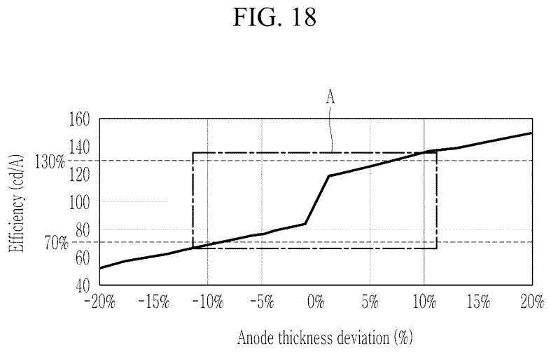

Drawbacks that may occur in case that the intermediate layer of the tandem structure as shown in FIG. 14 is stacked on the structure of the anode will be reviewed through FIG. 17 and FIG. 18.

FIG. 17 and FIG. 18 are drawings for explaining the distribution of light efficiency generated in comparative examples.

First, in FIG. 17, an intermediate layer EL having a thick thickness having a tandem structure is formed, and the anode is a double layer of a lower layer containing silver (Ag) and an upper layer containing ITO (Indium-Tin Oxide) is formed

The lower layer of the anode has the same thickness for all colors, but the upper layer has different thicknesses for each color.

Since the intermediate layer EL has the same thickness in all colors, an optical path length from the lower layer of the anode to the cathode is different for each color.

The optical path length allows light to resonate between the cathode and the anode, or more precisely, between the lower layer of the anode, so that light of a specific wavelength can be emitted to the top of the cathode, it constitutes a micro-cavity structure that allows.

According to this micro-cavity structure, the light partially reflected by the cathode having a transflective characteristic and provided back to the anode is repeatedly reflected from the anode, and the light between the anode and the cathode is repeated light causes interference and constructive interference, and an optical path length is set so that light of a wavelength corresponding to each color can be reinforced.

However, as shown in FIG. 16, in case that a step occurs at the anode, a constant optical path length is not maintained, and thus the wavelength at which constructive interference occurs is changed, resulting in lower light efficiency.

The degree to which light efficiency is lowered is shown in the graph of FIG. 18.

In FIG. 18, the light efficiency is simulated based on the blue pixel, and the degree of change in light efficiency according to the thickness deviation of the anode is expressed in %.

As shown in FIG. 18, it can be seen that the light efficiency is greatly changed even if the thickness is slightly out of the standard thickness,

as shown in the portion boxed with A in FIG. 18, it can be seen that in case that a thickness deviation of about 10% occurs, the light efficiency varies by about 30%.

Therefore, in case that a step occurs at the anode as in the comparative example of FIG. 16, the light efficiency is inevitably lowered.

In case that a small display device 100 such as a head-mounted display device is enlarged and viewed using the optical system 200, such a difference in light efficiency may be recognized as a deteriorate in display quality.

However, in the embodiment, since the conductive organic layer COL is formed under or below the anode to eliminate the step due to the contact hole OPan, the thickness deviation of the anode in FIG. 18 corresponds to 0, therefore, the light efficiency is 100% and has a constant merit.

Even if a small display device 100 such as a head-mounted display device is enlarged and viewed using the optical system 200, display quality may have merit.

Although embodiments have been described in detail above, the scope of the disclosure is not limited thereto, and various modifications and improvements will be understood by one of ordinary skill in the art using the disclosure and as defined in the following claims.

What is claimed is:

1. A display device, comprising:
a pixel driving circuit including a transistor and disposed on a substrate;
an organic layer covering the pixel driving circuit and including a contact hole;
a conductive organic layer covering the contact hole and the organic layer around the contact hole, and electrically connected to the transistor through the contact hole;
a non-conductive organic layer disposed above the organic layer and in a region where the conductive organic layer is not disposed; and
an anode electrically connected to the conductive organic layer,
wherein the contact hole overlaps the anode on a plan view.

2. The display device of claim 1, wherein
the conductive organic layer includes PEDOT: PSS, and
the non-conductive organic layer is a chemical formula structure in which a thiophene ring is broken in the PEDOT: PSS and separated into two OH groups.

3. The display device of claim 2, further comprising:
an anode protective layer disposed at an end of the anode; and
an inorganic insulating layer covering the anode protective layer and the non-conductive organic layer.

4. The display device of claim 3, wherein the inorganic insulating layer has a tip structure protruding from an upper surface of the anode protective layer.

5. The display device of claim 4, wherein
the anode protective layer includes indium-gallium-zinc oxide (IGZO),
the anode is formed of a double layer having a lower layer containing silver and an upper layer containing indium tin oxide (ITO),
the ITO of the upper layer of the anode is polycrystallized.

6. The display device of claim 4, further comprising:
a separator disposed above the organic layer and below the inorganic insulating layer and having a reverse tapered side surface;
an intermediate layer disposed above the anode and including an emission layer and a cathode; and
a separation intermediate layer separated from the intermediate layer on an upper surface of the separator, the intermediate layer being not continuously disposed on the reverse tapered side surface of the separator.

7. The display device of claim 6, wherein
the intermediate layer does not contact the anode protective layer below the inorganic insulating layer having the tip structure, and
an empty space is disposed between the intermediate layer and the anode protective layer.

8. The display device of claim 6, wherein the intermediate layer has a tandem structure including a plurality of emission layers.

9. The display device of claim 6, wherein
the separator is disposed below the non-conductive organic layer, and
the non-conductive organic layer and the inorganic insulating layer are disposed on the reverse tapered side surface of the separator.

10. The display device of claim 6, wherein
the separator is disposed on the non-conductive organic layer, and
the inorganic insulating layer is disposed on the reverse tapered side surface of the separator.

11. The display device of claim 6, further comprising:
a separation cathode separated from the cathode on an upper surface of the separator, the cathode being not continuously disposed on the reverse tapered side surface of the separator.

12. The display device of claim 3, further comprising:
an anode connection line covered by the organic layer and having a portion electrically connected to the conductive organic layer through the contact hole,
wherein the anode and the transistor are electrically connected to each other by the anode connection line and the conductive organic layer.

13. The display device of claim 1, wherein a head-mounted display device includes an optical system including a pair of curved lenses.

14. A method for manufacturing a display device, comprising:
forming a pixel driving circuit including a transistor and disposed on a substrate;
forming an organic layer including a contact hole on the substrate;
forming and planarizing a conductive organic material on the organic layer;
covering a first region of the conductive organic material using a first mask and exposing remaining regions of the conductive organic material;
changing an exposed region of the conductive organic material to have non-conductive properties through an oxidation process; and
forming an anode corresponding to the first region, wherein
the conductive organic material of the first region maintains conductivity to form a conductive organic layer, and
the exposed region of the conductive organic material is changed to non-conductive to form a non-conductive organic layer.

15. The method for manufacturing of display device of claim 14, wherein
the conductive organic material is PEDOT:PSS, and
the conductive organic material is separated into two OH groups as the thiophene ring is broken by the oxidation process to lose conductivity and change into a non-conductive organic layer.

16. The method for manufacturing of display device of claim 15, wherein
the oxidation process is performed by providing an insulating solution or an etchant capable of breaking the thiophene ring to the conductive organic material.

17. The method for manufacturing of display device of claim 14, wherein
the forming of the anode includes the step of additionally performing heat treatment,
the anode is formed of a double layer including a lower layer containing silver and an upper layer containing indium tin oxide (ITO), and
an ITO constituting the upper layer is polycrystallized by the heat treatment.

18. The method for manufacturing of display device of claim 14, further comprising:
forming an anode protective layer on the anode corresponding to the first region;
forming an inorganic insulating material exposing a portion of the anode protective layer except for an end thereof by dry etching using a second mask after laminating an inorganic insulating material; and
removing the exposed anode protective layer by wet etching.

19. The method for manufacturing of display device of claim 18, wherein
the anode protective layer is partially left at a tip of the anode through the wet etching, and
the inorganic insulating material is formed in a tip structure protruding from an upper surface of the remaining anode protective layer.

20. The method for manufacturing of display device of claim 18, wherein the anode protective layer includes indium-gallium-zinc oxide (IGZO).
